(19) United States
(12) Patent Application Publication
(10) Pub. No.: US 2026/0072365 A1
(43) Pub. Date: Mar. 12, 2026

(54) LITHOGRAPHY APPARATUS, LITHOGRAPHY METHOD, MEASUREMENT APPARATUS, AND ARTICLE MANUFACTURING METHOD

(71) Applicant: CANON KABUSHIKI KAISHA, Tokyo (JP)

(72) Inventor: ATSUSHI KUSAKA, Tochigi (JP)

(21) Appl. No.: 19/323,067

(22) Filed: Sep. 9, 2025

(30) Foreign Application Priority Data
Sep. 12, 2024 (JP) 2024-158481
Sep. 12, 2024 (JP) 2024-158483

(51) Int. Cl. G03F 9/00; G03F 7/00

(52) U.S. Cl. CPC G03F 9/7042; G03F 7/0002; G03F 9/7049; G03F 9/7065; G03F 9/7069; G03F 9/7076; G03F 9/7088; G03F 9/7092

(57) ABSTRACT

A lithography apparatus that forms a pattern in a curable composition on a substrate using an original, including a measurement unit configured to obtain a mark image by simultaneously capturing a first mark group provided in the original and a second mark group provided in the substrate, which exist in one field of view, and measure a relative position between the first mark group and the second mark group, and a control unit configured to align the original and the substrate based on the relative position while measuring the relative position by the measurement unit, wherein the control unit adjusts an image capturing condition for each region which includes an image of each mark of the first mark group and the second mark group.

### BACKGROUND

### Field of the Technology

The present disclosure relates to a lithography apparatus, a lithography method, a measurement method, and an article manufacturing method.

### Description of the Related Art

An imprint apparatus is an apparatus capable of transferring a nanoscale fine pattern, and has received attention as one of mass production lithography apparatuses for semiconductor devices, liquid crystal display devices, magnetic storage media, or the like. In the imprint apparatus, in order to accurately transfer the pattern of a mold serving as an original to an imprint material on a substrate, highly accurate alignment between the mold and the substrate is required.

In the imprint apparatus, as an alignment method between the substrate and the mold, a die-by-die alignment method is generally employed. The die-by-die alignment method is an alignment method in which, for each shot region on the substrate, a mold-side mark provided in the mold and a substrate-side mark provided in the substrate are optically detected, and a shift in positional relationship (relative position) between the mold and the substrate is corrected. The die-by-die alignment method is disclosed in Japanese U.S. Pat. No. 4,185,941 and Japanese Patent Laid-Open No. 2014-203935.

In alignment between the mold and the substrate, in order to implement a wide detection range, a mark group constituted of a plurality of kinds of marks is used as each of the mold-side mark and the substrate-side mark. However, when measuring the relative position (positional shift) between the substrate-side mark group and the mold-side mark group, the optical characteristic may be different between the marks constituting the mark group. In a case of simultaneously detecting these marks via the same optical system, it is impossible to perform adjustment for obtaining an excellent image (detection signal) from each mark, and this may affect the alignment accuracy between the mold and the substrate. Even when the optical characteristic is the same between the marks constituting the mark group, if uneven light is used to illuminate the marks, a similar problem occurs.

Furthermore, in a case of simultaneously detecting the marks constituting the mark group via the same optical system, stray light from a specific mark which is extremely bright or stray light from a mark other than the marks within the same field of view of the measurement apparatus may affect the other marks, and may be included as noise in the detection signal. Note that even when the optical characteristic is the same between the marks constituting the mark group, if uneven light is used to illuminate the marks, a similar problem occurs. These problems cause degradation in mark measurement accuracy.

### SUMMARY

The present disclosure provides a technique advantageous in alignment between an original and a substrate.

According to one aspect of the present disclosure, there is provided a lithography apparatus that forms a pattern in a curable composition on a substrate using an original, including a measurement unit configured to obtain a mark image by simultaneously capturing a first mark group provided in the original and a second mark group provided in the substrate, which exist in one field of view, and measure a relative position between the first mark group and the second mark group, and a control unit configured to align the original and the substrate based on the relative position while measuring the relative position by the measurement unit, wherein the control unit adjusts an image capturing condition for each region which includes an image of each mark of the first mark group and the second mark group.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic view illustrating configurations of an imprint apparatus according to an aspect of the present disclosure.

FIG. 2 is a schematic view illustrating configurations of an example of a measurement unit.

FIGS. 3A and 3B are views for specifically describing configurations of a mold-side mark group and a substrate-side mark group.

FIGS. 4A and 4B are schematic views each illustrating an example of an overlay image obtained by an image capturing unit.

FIG. 5A is a schematic view illustrating configurations of an example of the image capturing unit.

FIG. 5B is a schematic view illustrating configurations of an example of the image capturing unit.

FIG. 5C is a schematic view illustrating configurations of an example of the image capturing unit.

FIG. 5D is a schematic view illustrating configurations of an example of the image capturing unit.

FIG. 5E is a schematic view illustrating configurations of an example of the image capturing unit.

FIGS. 6A and 6B are views for describing setting of regions each of which includes the image of each mark of the mold-side mark group and the substrate-side mark group in the overlay image.

FIGS. 7A and 7B are views for describing setting of regions each of which includes the image of each mark of the mold-side mark group and the substrate-side mark group in the overlay image.

FIG. 8A is a schematic view illustrating configurations of an example of a measurement unit.

FIG. 8B is a schematic view illustrating configurations of an example of the measurement unit.

FIGS. 9A and 9B are schematic views illustrating configurations of examples of a reflection type adjustment mechanism and a transmission type adjustment mechanism, respectively.

FIG. 10 is a view illustrating an example of the reflectance or transmittance individually set for each region which includes the image of each mark of a mold-side mark group and a substrate-side mark group.

FIG. 11 is a view illustrating an example of the result of selecting reflective elements or transmissive elements for reflecting or transmitting light in a direction toward a mold and a substrate.

FIGS. 12A to 12D are views for describing temporal control of the reflective element or the transmissive element for each region which includes the image of each mark of the mold-side mark group and the substrate-side mark group.

FIGS. 13A to 13F are views for describing an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

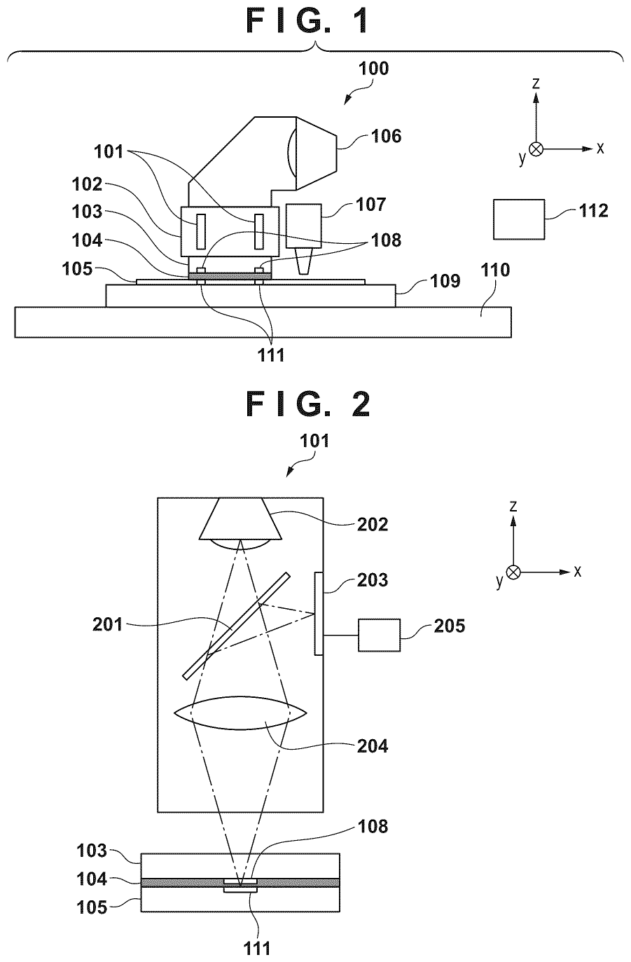

FIG. 1 is a schematic view illustrating configurations of an imprint apparatus 100 according to an aspect of the present disclosure. The imprint apparatus 100 is a lithography apparatus employed in a lithography step that is a manufacturing step for a device such as a semiconductor device, a liquid crystal display device, or magnetic storage medium as an article to form a pattern in a curable composition on a substrate. The imprint apparatus 100 brings an imprint material (curable composition) arranged (supplied or applied) on the substrate into contact with the mold, and applies curing energy to the imprint material, thereby forming a pattern of a cured product to which the pattern of the mold is transferred. For example, the imprint apparatus 100 arranges the imprint material on the substrate, and cures the imprint material in a state in which the mold formed with a pattern (concave and convex portions) is in contact with the imprint material on the substrate. The imprint apparatus 100 then increases the spacing between the mold and the substrate to separate (release) the mold from the cured imprint material on the substrate, thereby forming a pattern of the imprint material on the substrate. The series of processing performed in the imprint apparatus 100 as described above is generally referred to as an “imprint process”.

As the imprint material, a material (curable composition) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used.

The curable composition is a composition cured by light irradiation or heating. The photo-curable composition cured by light irradiation contains at least a polymerizable compound and a photopolymerization initiator, and may contain a nonpolymerizable compound or a solvent, as needed. The nonpolymerizable compound is at least one type of material selected from a group comprising of a sensitizer, a hydrogen donor, an internal mold release agent, a surfactant, an antioxidant, a polymer component, and the like.

The imprint material may be applied in a film shape onto the substrate by a spin coater or a slit coater. The imprint material may be applied, onto the substrate, in a droplet shape or in an island or film shape formed by connecting a plurality of droplets using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used, and a member made of a material different from that of the substrate may be formed on the surface of the substrate, as needed. More specifically, examples of the substrate include a silicon wafer, a semiconductor compound wafer, silica glass, and the like.

In the specification and the accompanying drawings, directions will be indicated on an XYZ coordinate system in which directions parallel to a plane on which the substrate is placed are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively.

The imprint apparatus 100 uses a mold 103 to mold an imprint material 104 on a substrate and form a pattern of the imprint material 104. As illustrated in FIG. 1, the imprint apparatus 100 includes a measurement unit 101 (measurement apparatus), an imprint head 102, a curing unit 106, an arranging unit 107, a substrate stage 109, a stage plate 110, and a control unit 112.

The mold 103 is, for example, an original in which a concave-convex pattern corresponding to the circuit pattern of the device is formed three-dimensionally, and is also called a mold. The mold 103 is made of, for example, a material such as quartz that can transmit light such as ultraviolet light. On a substrate 105, before the imprint material 104 is arranged, an adhesive film for improving adhesion between the imprint material 104 and the substrate 105 may be provided, as needed.

The curing unit 106 cures the imprint material 104 on the substrate by irradiating the imprint material 104 on the substrate with light via the mold 103. The curing unit 106 includes, for example, a light source such as a mercury lamp that emits light (curing light such as i-line or g-line) for curing the imprint material 104, an ellipse mirror that condenses the curing light emitted from the light source, and an optical system for applying the curing light to the imprint material 104. The optical system includes a lens, an aperture, and the like for shaping the curing light. The aperture is used to control the angle of view to apply the curing light only to the target shot region of the imprint process, to control peripheral light shielding to restrict irradiation of the curing light outside the shot region, and the like. The curing unit 106 may further include an optical integrator to evenly illuminate the mold 103.

The imprint head 102 includes a positioning mechanism for controlling the position of the mold 103 with respect to six axes, and a transfer mechanism for pressing the mold 103 against the imprint material 104 on the substrate and separating the mold 103 from the cured imprint material 104 on the substrate. Here, the six axes include the X, Y, and Z axes, and rotations around the respective axes.

The substrate stage 109 is configured to be movable with respect to the stage plate 110 while holding the substrate 105. The stage plate 110 is a member for movably supporting the substrate stage 109. The substrate stage 109 includes, for example, a positioning mechanism for controlling the position of the substrate 105 with respect to six axes.

The arranging unit 107 arranges (supplies or applies) the imprint material 104 on the substrate. In this embodiment, the imprint material 104 is an ultraviolet light curing resin having a property of curing upon irradiation of ultraviolet light. The arranging unit 107 includes, for example, a tank storing the imprint material 104, a plurality of nozzles that discharge, onto the substrate 105, the imprint material 104 supplied from the tank via supply paths, piezoelectric elements provided in the supply paths communicating the respective nozzles, and a discharge control unit. The discharge control unit controls the amount (discharge amount) and discharge timing of the imprint material 104 discharged as a droplet from one nozzle by adjusting a driving signal applied to the piezoelectric element.

The measurement unit 101 is configured to have a field of view capable of including a mark region that includes marks provided in each of the mold 103 and the substrate 105. For example, the measurement unit 101 includes four scopes that respectively detect the marks provided in four corners of each of the mold 103 and the shot region on the substrate. The measurement unit 101 captures the mark region of the target shot region of the imprint process via the mold 103 to obtain an image, and measures the relative position (positional shift) between a mold-side mark group 108 and a substrate-side mark group 111 based on the image. Note that the measurement unit 101 may be configured to have a field of view capable of including the entire shot region on the substrate. The mold-side mark group 108 (first mark group) is constituted of a plurality of (kinds of) marks provided in the mold 103. The substrate-side mark group 111 (second mark group) is constituted of a plurality of (kinds of) marks provided in the substrate 105. The substrate-side mark group 111 includes a plurality of marks that are provided for each shot region on the substrate and provided at different positions in the shot region. In this embodiment, at least one of the mold-side mark group 108 and the substrate-side mark group 111 includes a plurality of marks having different optical characteristics.

The control unit 112 is formed from a computer (information processing apparatus) including a CPU, a memory, and the like. The control unit 112 operates the imprint apparatus 100 by comprehensively controlling the respective units of the imprint apparatus 100 in accordance with a program stored in the storage unit. The control unit 112 controls an imprint process of forming a pattern of the imprint material 104 on the substrate by transferring the pattern of the mold 103 to the imprint material 104 on the substrate.

### First Embodiment

With reference to FIG. 2, a measurement unit 101 in the first embodiment will be specifically described. FIG. 2 is a schematic view illustrating configurations of an example of the measurement unit 101. The measurement unit 101 includes, for example, a mirror optical system 201, an illumination unit 202, an image capturing unit 203, an imaging optical system 204, and an image processing unit 205. In addition to the mirror optical system 201 and the imaging optical system 204, the measurement unit 101 may further include another optical system, more specifically, a lens, an aperture, a mirror, or the like.

The illumination unit 202 illuminates a substrate 105 via the imaging optical system 204 and a mold 103. The image capturing unit 203 captures the mark region including the mark provided in each of the mold 103 and the substrate 105 via the imaging optical system 204 and the mirror optical system 201, thereby obtaining an image. The image capturing unit 203 includes an image capturing device where a plurality of pixels are arrayed, each of which detects light from each mark of a mold-side mark group 108 and a substrate-side mark group 111. In this embodiment, the image capturing unit 203 is formed from the image capturing device that includes the plurality of pixels arrayed so as to be capable of capturing the mark region of at least one shot region on the substrate via the imaging optical system 204. More specifically, a CMOS sensor, a CCD sensor, a line sensor, or the like is used as the image capturing unit 203. The image processing unit 205 is formed from, for example, a computer (information processing apparatus) including a CPU, a memory, and the like. The image processing unit 205 processes the image obtained by the image capturing unit 203, and calculates the relative position between the mold-side mark group 108 and the substrate-side mark group 111 as a measurement result. Note that the control unit 112 may have the function of the image processing unit 205.

In the imprint apparatus 100 having the configurations as described above, while measuring the relative position (positional shift) between the mold-side mark group 108 and the substrate-side mark group 111 by the measurement unit 101, the mold 103 and the substrate 105 are aligned based on the relative position. Such alignment between the mold 103 and the substrate 105 is controlled by the control unit 112 as a part of an imprint process.

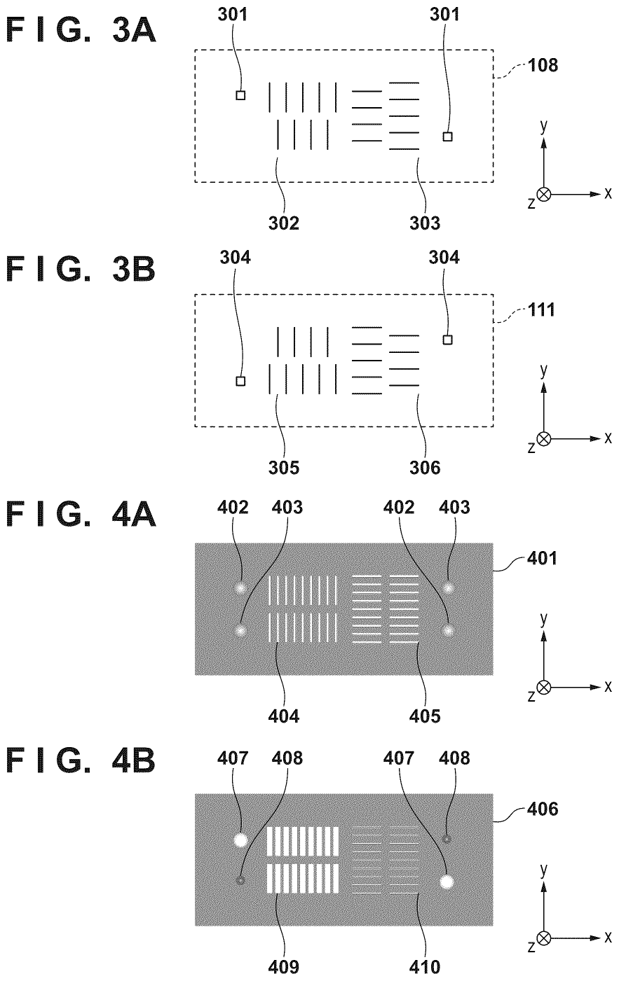

With reference to FIGS. 3A and 3B, configurations of the mold-side mark group 108 and the substrate-side mark group 111 will be specifically described.

FIG. 3A is a schematic view illustrating configurations of an example of the mold-side mark group 108. As illustrated in FIG. 3A, the mold-side mark group 108 includes, for example, a mold-side wide range mark 301 (first coarse detection mark), a mold-side high accuracy X mark 302 (first fine detection mark), and a mold-side high accuracy Y mark 303 (first fine detection mark).

The mold-side wide range mark 301 is a mark for widely measuring the positional shift of the mold 103 with respect to the center of the image capturing region (detection region) of the image capturing unit 203. The mold-side high accuracy X mark 302 is a mark for measuring the X-direction positional shift with the substrate-side mark group 111. The mold-side high accuracy Y mark 303 is a mark for measuring the Y-direction positional shift with the substrate-side mark group 111.

FIG. 3B is a schematic view illustrating configurations of an example of the substrate-side mark group 111. As illustrated in FIG. 3B, the substrate-side mark group 111 includes, for example, a substrate-side wide range mark 304 (second coarse detection mark), a substrate-side high accuracy X mark 305 (second fine detection mark), and a substrate-side high accuracy Y mark 306 (second fine detection mark).

The substrate-side wide range mark 304 is a mark for widely measuring the positional shift of the substrate 105 with respect to the center of the image capturing region (detection region) of the image capturing unit 203. The substrate-side high accuracy X mark 305 is a mark for measuring, in combination with the mold-side high accuracy X mark 302, the X-direction positional shift with the mold-side mark group 108. The substrate-side high accuracy Y mark 306 is a mark for measuring, in combination with the mold-side high accuracy Y mark 303, the Y-direction positional shift with the mold-side mark group 108.

Alignment between the mold 103 and the substrate 105 will be described below. FIG. 4A is a schematic view illustrating an example of an image obtained by the image capturing unit 203 during alignment between the mold 103 and the substrate 105, that is, an overlay image 401 (mark image) of the mark group provided in the mold 103 and the mark group provided in the substrate 105. Referring to FIG. 4A, the overlay image 401 includes a mold-side wide range mark image 402, a substrate-side wide range mark image 403, a high accuracy X mark overlay image 404, and a high accuracy Y mark overlay image 405.

The mold-side wide range mark image 402 is the image of the mold-side wide range mark 301 obtained by the image capturing unit 203. More specifically, first, light (illumination light) from the illumination unit 202 is applied to the mold-side wide range mark 301 via the imaging optical system 204. Then, light (reflected light) reflected by the mold-side wide range mark 301 is detected by the image capturing unit 203 via the imaging optical system 204 and the mirror optical system 201. Thus, the mold-side wide range mark image 402 is obtained.

The substrate-side wide range mark image 403 is the image of the substrate-side wide range mark 304 obtained by the image capturing unit 203. More specifically, first, light (illumination light) from the illumination unit 202 is applied to the substrate-side wide range mark 304 via the imaging optical system 204, the mold 103, and an imprint material 104. Then, light (reflected light) reflected by the substrate-side wide range mark 304 is detected by the image capturing unit 203 via the imprint material 104, the mold 103, the imaging optical system 204, and the mirror optical system 201. Thus, the substrate-side wide range mark image 403 is obtained.

The high accuracy X mark overlay image 404 is an image formed by overlaying (combining) the mold-side high accuracy X mark 302 and the substrate-side high accuracy X mark 305, and obtained by the image capturing unit 203. In this embodiment, the high accuracy X mark overlay image 404 is the image (interference fringe image) of the interference fringe formed due to the difference between the mark interval of the mold-side high accuracy X mark 302 and the mark interval of the substrate-side high accuracy X mark 305.

The high accuracy Y mark overlay image 405 is an image formed by overlaying (combining) the mold-side high accuracy Y mark 303 and the substrate-side high accuracy Y mark 306, and obtained by the image capturing unit 203. In this embodiment, the high accuracy Y mark overlay image 405 is the image (interference fringe image) of the interference fringe formed due to the difference between the mark interval of the mold-side high accuracy Y mark 303 and the mark interval of the substrate-side high accuracy Y mark 306.

Each of the mold-side wide range mark image 402, the substrate-side wide range mark image 403, the high accuracy X mark overlay image 404, and the high accuracy Y mark overlay image 405 is processed by the image processing unit 205 to calculate its position (measurement value).

As the processing method for the mold-side wide range mark image 402 and the substrate-side wide range mark image 403 in the image processing unit 205, for example, a method of detecting the peak position of an image including the mold-side wide range mark image 402 and the substrate-side wide range mark image 403 is used. As the processing method for the high accuracy X mark overlay image 404 and the high accuracy Y mark overlay image 405 in the image processing unit 205, for example, a method of fitting the interference fringe images using a trigonometric function or the like is used.

In these processing methods, in order to accurately calculate the measurement values from the mold-side wide range mark image 402, the substrate-side wide range mark image 403, the high accuracy X mark overlay image 404, and the high accuracy Y mark overlay image 405, it is necessary that each image (light amount thereof) is not saturated. Note that saturation of the image includes “highlight detail loss” caused by the excessive (equal to or more than the detection limit) amount of light (light amount) detected by the image capturing unit 203, and “shadow detail loss” caused by the insufficient (equal to or less than the detection limit) amount of light (light amount) detected by the image capturing unit 203.

If the optical characteristics, for example, the refractive indices of the mold 103 and the imprint material 104 filled between the mold-side mark group 108 (mold 103) and the substrate-side mark group 111 (substrate 105) are close to each other, sufficient reflected light cannot be obtained from the mold-side mark group 108. In this case, treatment for reflecting light is applied to the mold-side mark group 108. For example, a metal film is added. In addition, on the surface of the substrate 105, a planarization film for planarizing the surface, an adhesive film for improving the adhesion with the imprint material 104, a protection film which is required when processing the pattern of the imprint material 104, or the like may be added. Hence, the mold-side wide range mark image 402, the substrate-side wide range mark image 403, the high accuracy X mark overlay image 404, and the high accuracy Y mark overlay image 405 are obtained by the image capturing unit 203 via different paths. As a result, the amount of light detected by the image capturing unit 203 is different among the images in accordance with the wavelength of illumination light, the thickness of the imprint material 104, the kind and thickness of the metal film added to the mold-side mark group 108, the kind (optical characteristic) and thickness of the film added to the surface of the substrate 105, and the like.

FIG. 4B is a schematic view illustrating an example of an image obtained by the image capturing unit 203 during alignment between the mold 103 and the substrate 105, that is, an overlay image 406 (mark image) of the mark group provided in the mold 103 and the mark group provided in the substrate 105. Referring to FIG. 4B, each image is saturated in the overlay image 406. More specifically, the overlay image 406 includes a mold-side wide range mark image 407 with “highlight detail loss”, and a substrate-side wide range mark image 408 with “shadow detail loss”. Furthermore, the overlay image 406 includes a high accuracy X mark overlay image 409 with “highlight detail loss”, and a high accuracy Y mark overlay image 410 with “shadow detail loss”. Note that the combination of saturations of the images included in the overlay image 406, that is, the combination of “highlight detail loss” and “shadow detail loss” is arbitrary, and not limited to the combination illustrated in FIG. 4B. These images are obtained by the same image capturing unit 203 (measurement unit 101). Therefore, the image capturing condition by the image capturing unit 203, for example, the sensitivity including the range of light amount that the image capturing unit 203 can detect (the upper and lower limit values of the detection limit) is adjusted with respect to the whole overlay image 406 where the respective images are saturated. In this case, the image capturing unit 203 cannot obtain each image included in the overlay image 406 with the optimal light amount, unlike in FIG. 4A.

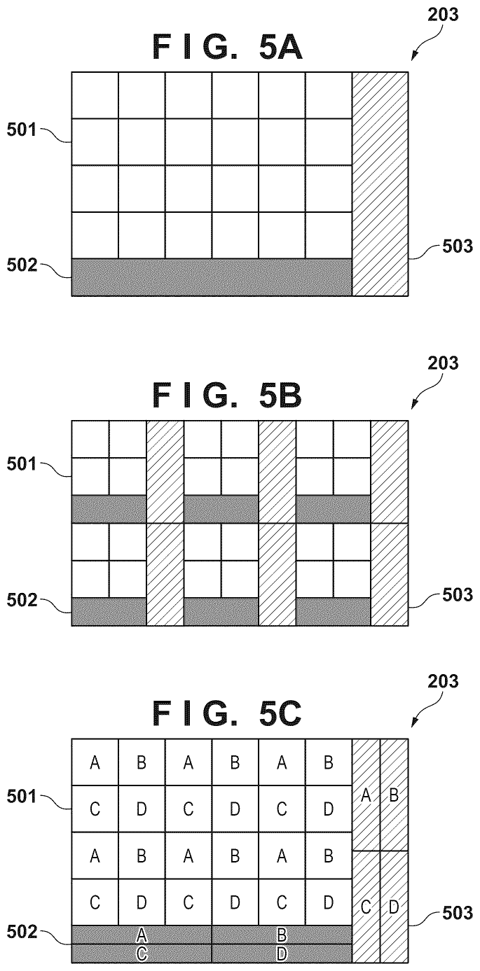

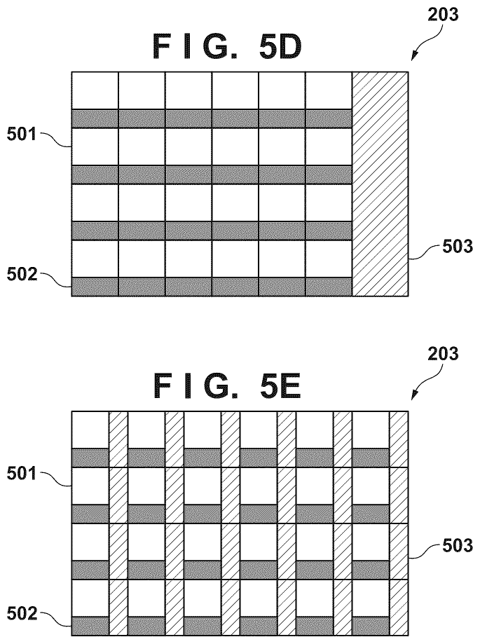

With reference to FIGS. 5A to 5E, specific configurations of the image capturing unit 203 will be described.

FIG. 5A is a schematic view illustrating an example of basic configurations of the image capturing unit 203. As illustrated in FIG. 5A, the image capturing unit 203 includes a plurality of pixels 501 arrayed in a grid, a pixel control unit 502, and a signal processing unit 503. The pixel 501 has a function of detecting (receiving) light from each mark of the mold-side mark group 108 and the substrate-side mark group 111, and includes, for example, a photodiode, a transistor switch, a microlens, a wavelength filter, an ND filter, and the like. The pixel control unit 502 has a function of controlling the pixel 501, and controls the image capturing condition by the image capturing unit 203 (the image capturing condition in the image capturing device), for example, the sensitivity, the accumulation time (exposure time), the gain, or the like. Here, the sensitivity is the sensitivity of detecting (receiving) light from each mark of the mold-side mark group 108 and the substrate-side mark group 111 by the pixel 501 (such as the range of light amount that the pixel 501 can detect). The accumulation time is the time of accumulating light from each mark of the mold-side mark group 108 and the substrate-side mark group 111 by the pixel 501. The gain is the gain at the time of converting, into a detection signal (electric signal), light from each mark of the mold-side mark group 108 and the substrate-side mark group 111 detected by the pixel 501. Note that the control unit 112 may have the function of the pixel control unit 502. The signal processing unit 503 has a function of processing the detection signal, and includes, for example, an AD converter, a signal amplifier, or the like.

In the image capturing unit 203 illustrated in FIG. 5A, only one pixel control unit 502 is provided to control all of the plurality of pixels 501. Therefore, the image capturing condition is adjusted with respect to all of the plurality of pixels 501. In other words, the image capturing condition cannot be adjusted individually for each of the plurality of pixels 501. In this case, as described with reference to FIG. 4B, it is impossible to obtain each image included in the overlay image 406 with the optimal light amount.

Therefore, in this embodiment, the image capturing unit 203 (measurement unit 101) is configured such that the image capturing condition can be adjusted for each region which includes the image of each mark of the mold-side mark group 108 and the substrate-side mark group 111 in the overlay image 406. More specifically, as illustrated in FIGS. 5B to 5E, the pixel control unit 502 is provided for a small number of pixels 501 of the plurality of pixels 501, or for each of the plurality of pixels 501, to enable adjustment of the image capturing condition. Note that the image of each mark of the mold-side mark group 108 and the substrate-side mark group 111 includes the mold-side wide range mark image 402, the substrate-side wide range mark image 403, the high accuracy X mark overlay image 404, and the high accuracy Y mark overlay image 405.

FIG. 5B is a schematic view illustrating configurations of an example of the image capturing unit 203 in this embodiment. The image capturing unit 203 illustrated in FIG. 5B is formed by miniaturizing the image capturing unit 203 illustrated in FIG. 5A, and arraying the miniaturized image capturing units 203 in a grid. In other words, the pixel control unit 502 is provided for a small number of pixels 501 of the plurality of pixels 501, in this embodiment, for four pixels 501 adjacent to each other. Hence, in the image capturing unit 203 illustrated in FIG. 5B, it is possible to adjust the image capturing condition for each region including four (a small number of) pixels 501 adjacent to each other (that is, it is possible to control the image capturing condition independently with four pixels 501 adjacent to each other as one unit).

FIG. 5C is a schematic view illustrating configurations of an example of the image capturing unit 203 in this embodiment. The image capturing unit 203 illustrated in FIG. 5C is formed by grouping the plurality of pixels 501 into a plurality of groups, and providing the pixel control unit 502 and the signal processing unit 503 for each group. In this embodiment, the plurality of pixels 501 are grouped into four groups (A, B, C, and D) each including six pixels 501 spaced apart from each other, and the pixel control unit 502 (and the signal processing unit 503) is provided for each group. Hence, in the image capturing unit 203 illustrated in FIG. 5C, it is possible to adjust the image capturing condition for each group including six (a small number of) pixels 501 spaced apart from each other (that is, it is possible to control the image capturing condition independently with the group as one unit).

FIG. 5D is a schematic view illustrating configurations of an example of the image capturing unit 203 in this embodiment. The image capturing unit 203 illustrated in FIG. 5D is formed by providing the pixel control unit 502 for each of the plurality of pixels 501. In other words, the pixel control unit 502 is provided for each pixel 501. Hence, in the image capturing unit 203 illustrated in FIG. 5D, it is possible to adjust the image capturing condition for each pixel 501 (that is, it is possible to control the image capturing condition independently with one pixel 501 as one unit).

FIG. 5E is a schematic view illustrating configurations of an example of the image capturing unit 203 in this embodiment. The image capturing unit 203 illustrated in FIG. 5E is formed by providing the pixel control unit 502 and the signal processing unit 503 for each of the plurality of pixels 501. In other words, the pixel control unit 502 (and the signal processing unit 503) is provided for each pixel 501. Hence, in the image capturing unit 203 illustrated in FIG. 5E, it is possible to adjust the image capturing condition for each pixel 501 (that is, it is possible to control the image capturing condition independently with one pixel 501 as one unit).

In this manner, in this embodiment, the image capturing unit 203 as illustrated in each of FIGS. 5B to 5E is formed in accordance with the image (the region which includes the image) of each mark of the mold-side mark group 108 and the substrate-side mark group 111 in the overlay image 406. Accordingly, in this embodiment, it is possible to adjust the image capturing condition by the image capturing unit 203 for each region which includes the image of each mark of the mold-side mark group 108 and the substrate-side mark group 111 in the overlay image 406.

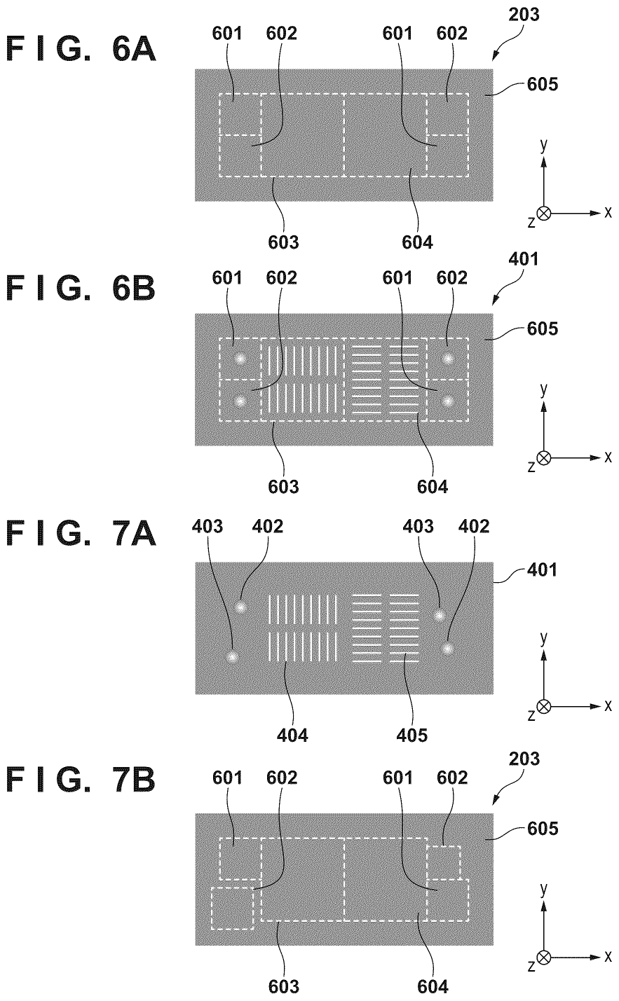

FIG. 6A is a schematic view illustrating an example of regions in the image capturing unit 203 each of which is set to include the image of each mark of the mold-side mark group 108 and the substrate-side mark group 111 in the overlay image 406, that is, regions for detecting (capturing) the respective marks. As illustrated in FIG. 6A, the image capturing unit 203 includes, as regions for detecting the respective marks, a mold-side wide range mark region 601, a substrate-side wide range mark region 602, a high accuracy X mark region 603, a high accuracy Y mark region 604, and a mark outside region 605. The mold-side wide range mark region 601 is a region for detecting the mold-side wide range mark 301 (mold-side wide range mark image 402) of the mold-side mark group 108. The substrate-side wide range mark region 602 is a region for detecting the substrate-side wide range mark 304 (substrate-side wide range mark image 403) of the substrate-side mark group 111. The high accuracy X mark region 603 is a region for detecting the mold-side high accuracy X mark 302 of the mold-side mark group 108 and the substrate-side high accuracy X mark 305 of the substrate-side mark group 111 (high accuracy X mark overlay image 404). The high accuracy Y mark region 604 is a region for detecting the mold-side high accuracy Y mark 303 of the mold-side mark group 108 and the substrate-side high accuracy Y mark 306 of the substrate-side mark group 111 (high accuracy Y mark overlay image 405). The mark outside region 605 is a region where the marks of the mold-side mark group 108 and the substrate-side mark group 111 do not exist. These regions are set by the pixel control unit 502 or the control unit 112, basically, based on the design information (design dimension) of each mark of the mold-side mark group 108 and the substrate-side mark group 111.

FIG. 6B is a schematic view illustrating a state in which the regions 601 to 605 set in the image capturing unit 203 illustrated in FIG. 6A are superimposed on the overlay image 401 illustrated in FIG. 4A. As illustrated in FIG. 6B, the regions 601 to 604 of the image capturing unit 203 are set to respectively include the images of the marks of the mold-side mark group 108 and the substrate-side mark group 111 in the overlay image 406. Hence, in this embodiment, it is possible to adjust the image capturing condition for each of the regions 601 to 604 of the image capturing unit 203, that is, for each region which includes the image of each mark of the mold-side mark group 108 and the substrate-side mark group 111 in the overlay image 406.

Therefore, in this embodiment, for each region which includes the image of each mark of the mold-side mark group 108 and the substrate-side mark group 111 in the overlay image 406, the image capturing condition by the image capturing unit 203, that is, at least one of the sensitivity, the accumulation time, and the gain is adjusted such that the image is not saturated. More specifically, for each region which includes the image of each mark of the mold-side mark group 108 and the substrate-side mark group 111 in the overlay image 406, the image capturing condition by the image capturing unit 203 is adjusted such that a peak appears in the waveform obtained from the image of each mark. For example, if the sensitivity is adjusted as the image capturing condition by the image capturing unit 203, the sensitivity is lowered for the region which includes the mark image with highlight detail loss, and the sensitivity is raised for the region which includes the mark image with shadow detail loss. With this, it is possible to obtain each image included in the overlay image 406 with the optimal light amount, and highly accurately obtain (measure) the position of the mark corresponding to each image.

In this embodiment, by the measurement unit 101 (image capturing unit 203) formed as described above, the relative position between the mold-side mark group 108 (mold 103) and the substrate-side mark group 111 (substrate 105) is measured, and the mold 103 and the substrate 105 are aligned based on the relative position.

More specifically, first, the mold-side mark group 108 and the substrate-side mark group 111 existing in one field of view of the image capturing unit 203 (image capturing device) are simultaneously captured by the image capturing unit 203 to obtain the overlay image 401. With this, the mold-side wide range mark image 402, the substrate-side wide range mark image 403, the high accuracy X mark overlay image 404 (interference fringe), and the high accuracy Y mark overlay image 405 (interference fringe) are obtained simultaneously.

Then, the positions of the mold-side wide range mark image 402 and the substrate-side wide range mark image 403 with respect to the image capturing region of the image capturing unit 203 (image capturing device) are specified, and the positional relationship between the mold-side mark group 108 and the substrate-side mark group 111 is obtained. At the same time, the highly accurate positional relationship between the mold-side mark group 108 and the substrate-side mark group 111 is obtained from the high accuracy X mark overlay image 404 and the high accuracy Y mark overlay image 405.

Here, in this embodiment, since the high accuracy X mark overlay image 404 and the high accuracy Y mark overlay image 405 are interference fringes, in principle, a positional shift larger than the period of the interference fringe cannot be measured. In other words, if the positional relationship between the mold-side mark group 108 and the substrate-side mark group 111 obtained from the mold-side wide range mark image 402 and the substrate-side wide range mark image 403 is not larger than the period of the interference fringe, the highly accurate positional relationship between the mold-side mark group 108 and the substrate-side mark group 111 can be obtained. Accordingly, the resolution of each of the mold-side wide range mark 301 and the substrate-side wide range mark 304 needs to be equal to or lower than the period of the interference fringe generated by the overlay (composition) of the mold-side high accuracy mark and the substrate-side high accuracy mark. Note that the mold-side high accuracy mark includes the mold-side high accuracy X mark 302 and the mold-side high accuracy Y mark 303, and the substrate-side high accuracy mark includes the substrate-side high accuracy X mark 305 and the substrate-side high accuracy Y mark 306. The positional relationship obtained from these high accuracy marks is expressed by the measurement value of the high accuracy mark to which the product of the integer value of the quotient between the wide range mark and the period of the interference fringe and the period of the interference fringe is added.

In this embodiment, from the positional relationship between the substrate-side mark group 111 provided in the shot region on the substrate and the corresponding mold-side mark group 108, and the design position of the substrate-side mark group 111 in the shot region, the positional relationship between the shot region and the mold 103 (the pattern thereof) is obtained. The positional relationship between the shot region on the substrate and the mold 103 (the positional relationship between the mold 103 and the substrate 105) includes, for example, X translation, Y translation, rotation, X magnification, Y magnification, a diamond shape, and the like. As for the positional relationship between the shot region on the substrate and the mold 103, X translation, Y translation, and rotation are reflected on the driving instruction value of the substrate stage 109, and the substrate stage 109 is driven so as to reduce the alignment error. X magnification, Y magnification, and the diamond shape are reflected on the driving instruction value of a magnification/shape correction mechanism, and the magnification/shape correction mechanism is driven so as to reduce the alignment error. The magnification/shape correction mechanism is implemented as, for example, a mechanism that deforms the mold 103 (pattern thereof) by applying a force to the side surface of the mold 103, or a mechanism that deforms the substrate 105 (shot region thereof) by applying heat to the substrate 105. Note that the positional relationship between the shot region on the substrate and the mold 103, and the method of correcting the positional relationship are not limited. In this manner, the mold 103 and the substrate 105 are aligned by repeating the alignment operation while obtaining the positional relationship between the mold 103 and the substrate 105 by simultaneously capturing the mold-side mark group 108 and the substrate-side mark group 111 to obtain the overlay image 401.

Setting of the region (the mold-side wide range mark region 601, the substrate-side wide range mark region 602, the high accuracy X mark region 603, or the high accuracy Y mark region 604) including the image of each mark of the mold-side mark group 108 and the substrate-side mark group 111 in the overlay image 406 will be described. The region which includes the image of each mark of the mold-side mark group 108 and the substrate-side mark group 111 in the overlay image 406 is set by, for example, the pixel control unit 502, and basically set based on the design information of each mark, as described above.

However, there can be a case where the position of the substrate-side mark group 111 is shifted with respect to the image capturing region (field of view) of the image capturing unit 203, as illustrated in FIG. 7A. In this case, even if the region which includes the image of each mark is set based on the design information of each mark of the mold-side mark group 108 and the substrate-side mark group 111, for example, the substrate-side wide range mark 304 may not be detected in the substrate-side wide range mark region 602. Therefore, as illustrated in FIG. 7B, the region which includes the image of each mark may be set based on the position of the image of each mark of the mold-side mark group 108 and the substrate-side mark group 111 in the overlay image 406 (mark image) obtained by the image capturing unit 203. In other words, the region for detecting the mark may be set in the image capturing unit 203 (image capturing device) so as to include the image of each mark of the mold-side mark group 108 and the substrate-side mark group 111 in the overlay image 406. FIG. 7A is a schematic view illustrating an example of the overlay image 401 obtained by the image capturing unit 203, and FIG. 7B is a schematic view illustrating a state in which the regions 601 to 605 set in the image capturing unit 203 are superimposed on the overlay image 401 illustrated in FIG. 7A.

During alignment between the mold 103 and the substrate 105, by repeating the alignment operation, the positional relationship between the mold-side mark group 108 and the substrate-side mark group 111 dynamically fluctuates. Therefore, during a period of alignment between the mold 103 and the substrate 105, the region which includes the image of each mark is preferably set dynamically based on the position of the image of each mark of the mold-side mark group 108 and the substrate-side mark group 111 in the overlay image 406 obtained by the image capturing unit 203.

There can be a case where, when starting alignment between the mold 103 and the substrate 105, the positional relationship between the mold-side mark group 108 and the substrate-side mark group 111 is significantly shifted. In this case, it is assumed that the image of each mark of the mold-side mark group 108 and the substrate-side mark group 111 is not included in the overlay image 406 obtained by the image capturing unit 203. Accordingly, each mark cannot be detected in the region set based on the design information of each mark of the mold-side mark group 108 and the substrate-side mark group 111. In this case, in the image capturing unit 203, the settings of the regions for detecting the respective marks are canceled, and the overlay image 406 is obtained by adjusting the image capturing conditions to the same condition in the entire area of the image capturing region of the image capturing unit 203. Then, a search of the image of each mark of the mold-side mark group 108 and the substrate-side mark group 111 is performed in the overlay image 406, and regions for detecting the respective marks are newly set in the image capturing unit 203 so as to include the images of the respective marks detected by the search.

Note that, in this embodiment, a case where the positional relationship between the mold-side mark group 108 and the substrate-side mark group 111 is significantly shifted is taken as an example, and adjusting the image capturing conditions to the same condition in the entire area of the image capturing region of the image capturing unit 203 has been described. However, adjusting the image capturing conditions to the same condition in the entire area of the image capturing region of the image capturing unit 203 is also useful in a case where the image capturing condition has not been adjusted appropriately for the region for detecting the image of each mark of the mold-side mark group 108 and the substrate-side mark group 111. For example, if the sensitivity in each region is not appropriate, by setting the uniform sensitivity in the entire area of the image capturing region, it is possible to search for the image of each mark of the mold-side mark group 108 and the substrate-side mark group 111.

In this manner, in this embodiment, the imprint apparatus 100 can obtain the image of each mark of the mold-side mark group 108 and the substrate-side mark group 111 with the optimal light amount, and highly accurately obtain (measure) the position of the mark corresponding to each image. Hence, according to this embodiment, a technique advantageous in alignment between the mold 103 and the substrate 105 can be provided.

### Second Embodiment

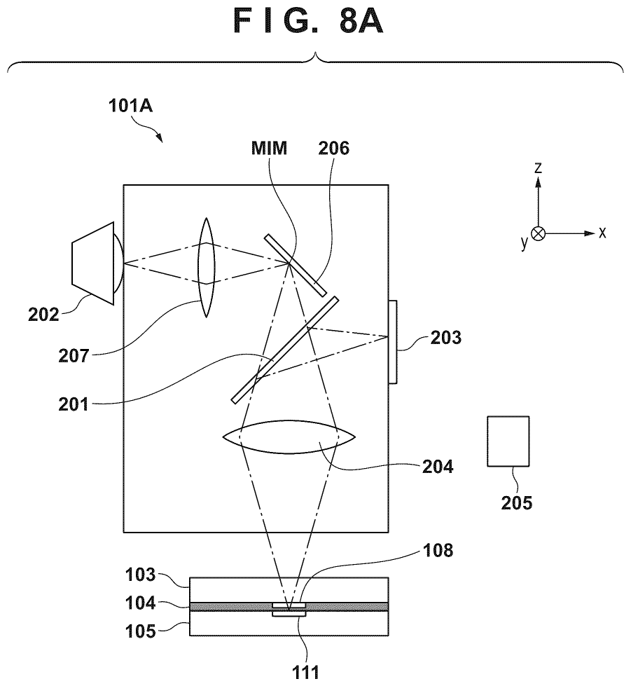

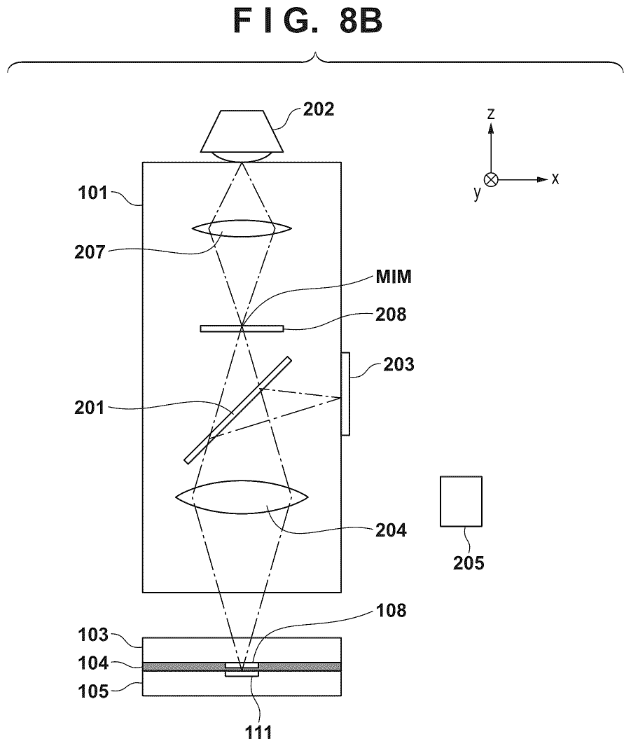

With reference to FIGS. 8A and 8B, a measurement unit 101 in the second embodiment will be specifically described. FIGS. 8A and 8B are schematic views each illustrating configurations of an example of the measurement unit 101. In this embodiment, the measurement unit 101 measures the relative position between a mold-side mark group 108 and a substrate-side mark group 111 from an overlay image (mark image) obtained by capturing the mold-side mark group 108 and the substrate-side mark group 111 existing in one field of view. In order to adjust the amount of light reaching the image capturing unit from the mold-side mark group 108 and the substrate-side mark group 111 (light detected by the image capturing unit), the measurement unit 101 includes an adjustment unit that adjusts the amount of light for illuminating the mold-side mark group 108 and the substrate-side mark group 111. The adjustment unit that adjusts the amount of light for illuminating the mold-side mark group 108 and the substrate-side mark group 111 is implemented as a reflection type adjustment mechanism or a transmission type adjustment mechanism, as illustrated in FIGS. 8A and 8B.

As an example of the measurement unit 101, FIG. 8A illustrates configurations of a measurement unit 101A including a reflection type adjustment mechanism 206. The measurement unit 101A includes, for example, a mirror optical system 201, an illumination unit 202, an image capturing unit 203, a first imaging optical system 204, an image processing unit 205, the reflection type adjustment mechanism 206, and a second imaging optical system 207. In addition to the mirror optical system 201, the first imaging optical system 204, the reflection type adjustment mechanism 206, and the second imaging optical system 207, the measurement unit 101A may further include another optical system, more specifically, a lens, an aperture, a mirror, or the like.

The illumination unit 202 illuminates a substrate 105 via the second imaging optical system 207, the reflection type adjustment mechanism 206, the first imaging optical system 204, and a mold 103. The image capturing unit 203 captures the mark region including the mark provided in each of the mold 103 and the substrate 105 via the first imaging optical system 204 and the mirror optical system 201, thereby obtaining an image. The image capturing unit 203 includes an image capturing device where a plurality of pixels are arrayed, each of which detects light from each mark of the mold-side mark group 108 and the substrate-side mark group 111. In this embodiment, the image capturing unit 203 is formed from the image capturing device that includes the plurality of pixels arrayed so as to be capable of capturing the mark region of at least one shot region on the substrate via the first imaging optical system 204. More specifically, a CMOS sensor, a CCD sensor, a line sensor, or the like is used as the image capturing unit 203. The image processing unit 205 is formed from, for example, a computer (information processing apparatus) including a CPU, a memory, and the like. The image processing unit 205 processes the image obtained by the image capturing unit 203, and calculates the relative position between the mold-side mark group 108 and the substrate-side mark group 111 as a measurement result. Note that a control unit 112 may have the function of the image processing unit 205.

The reflection type adjustment mechanism 206 includes, for example, a digital micromirror device or a reflective liquid crystal device. In this embodiment, the reflection type adjustment mechanism 206 is configured to be capable of adjusting the reflectance and reflection angle with respect to the illumination light for each arbitrary region set in the reflection region where light (illumination light) from the illumination unit 202 is reflected. The reflection type adjustment mechanism 206 may be combined with a wavelength filter to be capable of adjusting the reflectance for each wavelength of the illumination light. With this, in a case where the illumination light includes a plurality of wavelengths, it is possible to select the wavelength of the illumination light and adjust the reflectance for each arbitrary region set in the reflection region. The reflection type adjustment mechanism 206 may also be combined with an ND filter to enlarge the adjustment range of reflectance.

As an example of the measurement unit 101, FIG. 8B illustrates configurations of a measurement unit 101B including a transmission type adjustment mechanism 208. The measurement unit 101B includes, for example, the mirror optical system 201, the illumination unit 202, the image capturing unit 203, the first imaging optical system 204, the image processing unit 205, the second imaging optical system 207, and the transmission type adjustment mechanism 208. In addition to the mirror optical system 201, the first imaging optical system 204, the second imaging optical system 207, and the transmission type adjustment mechanism 208, the measurement unit 101B may further include another optical system, more specifically, a lens, an aperture, a mirror, or the like.

The illumination unit 202 illuminates the substrate 105 via the second imaging optical system 207, the transmission type adjustment mechanism 208, the first imaging optical system 204, and the mold 103. The image capturing unit 203 captures the mark region including the mark provided in each of the mold 103 and the substrate 105 via the first imaging optical system 204 and the mirror optical system 201, thereby obtaining an image. Note that the specific configurations and functions of the image capturing unit 203 and the image processing unit 205 are as described above, and a detailed description here is omitted.

The transmission type adjustment mechanism 208 includes, for example, a transmissive liquid crystal device. In this embodiment, the transmission type adjustment mechanism 208 is configured to be capable of adjusting the transmittance with respect to the illumination light for each arbitrary region set in the transmission region where light (illumination light) from the illumination unit 202 is transmitted. The transmission type adjustment mechanism 208 may be combined with a wavelength filter to be capable of adjusting the transmittance for each wavelength of the illumination light. With this, in a case where the illumination light includes a plurality of wavelengths, it is possible to select the wavelength of the illumination light and adjust the transmittance for each arbitrary region set in the transmission region. The transmission type adjustment mechanism 208 may also be combined with an ND filter to enlarge the adjustment range of transmittance.

In an imprint apparatus 100 having the configurations as described above, while measuring the relative position (positional shift) between the mold-side mark group 108 and the substrate-side mark group 111 by the measurement unit 101, the mold 103 and the substrate 105 are aligned based on the relative position. Alignment between the mold 103 and the substrate 105 is controlled by the control unit 112 as a part of an imprint process (that is, the control unit 112 functions as an alignment unit that aligns the mold 103 and the substrate 105).

The specific configurations of the mold-side mark group 108 and the substrate-side mark group 111 are as described with reference to FIGS. 3A and 3B in the first embodiment.

Similar to the first embodiment, alignment between the mold 103 and the substrate 105 will be described below with reference to FIGS. 4A and 4B.

A mold-side wide range mark image 402 is the image of a mold-side wide range mark 301 obtained by the image capturing unit 203. More specifically, first, light (illumination light) from the illumination unit 202 is applied to the mold-side wide range mark 301 via the second imaging optical system 207, the reflection type adjustment mechanism 206 or the transmission type adjustment mechanism 208, and the first imaging optical system 204. Then, light (detection light) reflected by the mold-side wide range mark 301 is detected by the image capturing unit 203 via the first imaging optical system 204 and the mirror optical system 201. Thus, the mold-side wide range mark image 402 is obtained.

A substrate-side wide range mark image 403 is the image of a substrate-side wide range mark 304 obtained by the image capturing unit 203. More specifically, first, light (illumination light) from the illumination unit 202 is applied to the substrate-side wide range mark 304 via the second imaging optical system 207, the reflection type adjustment mechanism 206 or the transmission type adjustment mechanism 208, the first imaging optical system 204, the mold 103, and an imprint material 104. Then, light (detection light) reflected by the substrate-side wide range mark 304 is detected by the image capturing unit 203 via the imprint material 104, the mold 103, the first imaging optical system 204, and the mirror optical system 201. Thus, the substrate-side wide range mark image 403 is obtained.

As in the first embodiment, a high accuracy X mark overlay image 404 is an image formed by overlaying (combining) a mold-side high accuracy X mark 302 and a substrate-side high accuracy X mark 305, and obtained by the image capturing unit 203. As in the first embodiment, a high accuracy Y mark overlay image 405 is an image formed by overlaying (combining) a mold-side high accuracy Y mark 303 and a substrate-side high accuracy Y mark 306, and obtained by the image capturing unit 203.

Each of the mold-side wide range mark image 402, the substrate-side wide range mark image 403, the high accuracy X mark overlay image 404, and the high accuracy Y mark overlay image 405 is processed by the image processing unit 205 to calculate its position (measurement value).

The processing methods for the mold-side wide range mark image 402, the substrate-side wide range mark image 403, the high accuracy X mark overlay image 404, and the high accuracy Y mark overlay image 405 in the image processing unit 205 are similar to those in the first embodiment, and a detailed description here is omitted.

As described above, in order to accurately calculate the measurement values from the mold-side wide range mark image 402, the substrate-side wide range mark image 403, the high accuracy X mark overlay image 404, and the high accuracy Y mark overlay image 405, it is necessary that each image (light amount thereof) is not saturated.

If the optical characteristics, for example, the refractive indices of the mold 103 and the imprint material 104 filled between the mold-side mark group 108 (mold 103) and the substrate-side mark group 111 (substrate 105) are close to each other, sufficient detection light cannot be obtained from the mold-side mark group 108. In this case, treatment for reflecting illumination light is applied to the mold-side mark group 108. For example, a metal film is added. In addition, on the surface of the substrate 105, a planarization film for planarizing the surface, an adhesive film for improving the adhesion with the imprint material 104, a protection film which is required when processing the pattern of the imprint material 104, or the like may be added. Hence, the mold-side wide range mark image 402, the substrate-side wide range mark image 403, the high accuracy X mark overlay image 404, and the high accuracy Y mark overlay image 405 are obtained by the image capturing unit 203 via different paths. As a result, the amount of light detected by the image capturing unit 203 is different among the images in accordance with the wavelength of illumination light, the thickness of the imprint material 104, the kind and thickness of the metal film added to the mold-side mark group 108, the kind (optical characteristic) and thickness of the film added to the surface of the substrate 105, and the like.

Referring to FIG. 4B, each image is saturated in an overlay image 406. More specifically, the overlay image 406 includes a mold-side wide range mark image 407 with “highlight detail loss” and a substrate-side wide range mark image 408 with “shadow detail loss”. Furthermore, the overlay image 406 includes a high accuracy X mark overlay image 409 with “highlight detail loss”, and a high accuracy Y mark overlay image 410 with “shadow detail loss”. These images are obtained by the same image capturing unit 203 (measurement unit 101). Therefore, the amount of light for illuminating the mold-side mark group 108 and the substrate-side mark group 111 (marks thereof) is adjusted with respect to the whole overlay image 406 where the respective images are saturated. In this case, the image capturing unit 203 cannot obtain each image included in the overlay image 406 with the optimal light amount, unlike in FIG. 4A.

With reference to FIGS. 9A and 9B, the specific arrangement of each of the reflection type adjustment mechanism 206 and the transmission type adjustment mechanism 208 will be described. In this embodiment, each of the reflection type adjustment mechanism 206 and the transmission type adjustment mechanism 208 is configured to be capable of adjusting the amount of light for illuminating each mark for each region which includes the image of each mark of the mold-side mark group 108 and the substrate-side mark group 111 in the overlay image 406.

FIG. 9A is a schematic view illustrating configurations of an example of the reflection type adjustment mechanism 206. As illustrated in FIG. 9A, the reflection type adjustment mechanism 206 includes a plurality of reflective elements 5011 arrayed in a grid in a reflection region, a reflection driving unit 5021, and a reflection control unit 5031.

The reflective element 5011 is an element having a reflection structure of reflecting light entering from the illumination unit 202 via the second imaging optical system 207. The reflective element 5011 includes, for example, a micromirror device or a reflective liquid crystal device.

The reflection driving unit 5021 is a unit for independently driving each reflective element 5011 to the first state or the second state (for changing the posture of the reflective element 5011). Here, the first state is a state in which the reflective element 5011 reflects light from the illumination unit 202 in a direction toward the mold 103 (mold-side mark group 108) and the substrate 105 (substrate-side mark group 111) (that is, the mold 103 and the substrate 105 are illuminated with light reflected by the reflective element 5011). The second state is a state in which the reflective element 5011 reflects light from the illumination unit 202 in a direction different from the direction toward the mold 103 and the substrate 105 (that is, the mold 103 and the substrate 105 are not illuminated with light reflected by the reflective element 5011).

The reflection control unit 5031 independently controls each reflective element 5011 via the reflection driving unit 5021. For example, the reflection control unit 5031 controls the reflectance of an arbitrary region set in the reflection region by selecting the state of each reflective element 5011 to be the first state or the second state (the reflective element 5011 that reflects light in the direction toward the mold 103 and the substrate 105). Note that the control unit 112 may have the function of the reflection control unit 5031.

In this manner, in this embodiment, the reflection type adjustment mechanism 206 can adjust the amount of light for illuminating the mold-side mark group 108 and the substrate-side mark group 111 for each arbitrary region set in the reflection region, and furthermore, with the reflective element 5011 as one unit (region).

FIG. 9B is a schematic view illustrating configurations of an example of the transmission type adjustment mechanism 208. As illustrated in FIG. 9B, the transmission type adjustment mechanism 208 includes a plurality of transmissive elements 5051 arrayed in a grid in a transmission region, a transmission driving unit 5061, and a transmission control unit 5071.

The transmissive element 5051 is an element having a transmission structure of transmitting light entering from the illumination unit 202 via the second imaging optical system 207. The transmissive element 5051 includes, for example, a transmissive liquid crystal device.

The transmission driving unit 5061 is a unit for independently driving each transmissive element 5051 to the third state or the fourth state. Here, the third state is a state in which the transmissive element 5051 transmits light from the illumination unit 202 in a direction toward the mold 103 (mold-side mark group 108) and the substrate 105 (substrate-side mark group 111) (that is, the mold 103 and the substrate 105 are illuminated with light transmitted through the transmissive element 5051). The fourth state is a state in which the transmissive element 5051 does not transmit light from the illumination unit 202 in a direction toward the mold 103 and the substrate 105 (that is, the transmissive element 5051 blocks the light so the mold 103 and the substrate 105 are not illuminated with the light).

The transmission control unit 5071 independently controls each transmissive element 5051 via the transmission driving unit 5061. For example, the transmission control unit 5071 controls the transmittance of an arbitrary region set in the transmission region by selecting the state of each transmissive element 5051 from the third state and the fourth state (the transmissive element 5051 transmits light in the direction toward the mold 103 and the substrate 105). Note that the control unit 112 may have the function of the transmission control unit 5071.

In this manner, in this embodiment, the transmission type adjustment mechanism 208 can adjust the amount of light for illuminating the mold-side mark group 108 and the substrate-side mark group 111 for each arbitrary region set in the transmission region, and furthermore, with the transmissive element 5051 as one unit (region).

Here, the arrangement positions of the reflection type adjustment mechanism 206 and the transmission type adjustment mechanism 208 will be described. In FIGS. 8A and 8B, each of the reflection type adjustment mechanism 206 and the transmission type adjustment mechanism 208 is arranged at an intermediate imaging position MIM of light for illuminating the mold-side mark group 108 and the substrate-side mark group 111. However, in practice, considering the influence of each of the reflective elements 5011 and the transmissive elements 5051 arrayed in a grid, each of the reflection type adjustment mechanism 206 and the transmission type adjustment mechanism 208 is preferably arranged at a defocus position defocused from the intermediate imaging position MIM. For example, in order to prevent that imaging of each of the reflective elements 5011 and the transmissive elements 5051 arrayed in a grid influences the mark measurement accuracy, it is necessary to generate a blur equal to or greater than the array pitch of each of the reflective elements 5011 and the transmissive elements 5051. More specifically, each of the reflection type adjustment mechanism 206 and the transmission type adjustment mechanism 208 is preferably arranged at a defocus position where the illuminance unevenness of light entering the mold-side mark group 108 and the substrate-side mark group 111 via each of the reflection type adjustment mechanism 206 and the transmission type adjustment mechanism 208 becomes 10% or less. Therefore, the measurement unit 101 may further include a moving mechanism that moves each of the reflection type adjustment mechanism 206 and the transmission type adjustment mechanism 208 to the defocus position.

In the image capturing unit 203, regions each set to include the image of each mark of the mold-side mark group 108 and the substrate-side mark group 111 in the overlay image 406, that is, regions for detecting (capturing) the respective marks are as illustrated in FIG. 6A, as in the first embodiment. The image capturing unit 203 includes, as regions for detecting the respective marks, a mold-side wide range mark region 601, a substrate-side wide range mark region 602, a high accuracy X mark region 603, a high accuracy Y mark region 604, and a mark outside region 605. These regions are set by the pixel control unit 502 or the control unit 112, basically, based on the design information (design dimension) of each mark of the mold-side mark group 108 and the substrate-side mark group 111.

A state in which the regions 601 to 605 set in the image capturing unit 203 illustrated in FIG. 6A are superimposed on the overlay image 401 illustrated in FIG. 4A is as illustrated in FIG. 6B, as in the first embodiment. As illustrated in FIG. 6B, each of the regions 601 to 604 of the image capturing unit 203 is set to include the image of each mark of the mold-side mark group 108 and the substrate-side mark group 111 in the overlay image 406.

In this embodiment, arbitrary regions are set in the reflection region of the reflection type adjustment mechanism 206 or the transmission region of the transmission type adjustment mechanism 208 in accordance (synchronization) with the regions 601 to 605 set in the image capturing unit 203. In other words, in the reflection region of the reflection type adjustment mechanism 206 or the transmission region of the transmission type adjustment mechanism 208, arbitrary regions for adjusting the amount of light for illuminating the mold-side mark group 108 and the substrate-side mark group 111 are set so as to correspond to the regions 601 to 605, respectively. Therefore, in this embodiment, it is possible to adjust the amount of light for illuminating the mold-side mark group 108 and the substrate-side mark group 111 via the reflection type adjustment mechanism 206 or the transmission type adjustment mechanism 208 for each region which includes the image of each mark of the mold-side mark group 108 and the substrate-side mark group 111. Note that the reflection type adjustment mechanism 206 and the transmission type adjustment mechanism 208 may be collectively referred to as an adjustment unit hereinafter.

In this embodiment, for each region which includes the image of each mark of the mold-side mark group 108 and the substrate-side mark group 111, the amount of light for illuminating the mold-side mark group 108 and the substrate-side mark group 111 is adjusted via the adjustment unit to prevent saturation of the image. More specifically, for each region which includes the image of each mark of the mold-side mark group 108 and the substrate-side mark group 111, the amount of light for illuminating the mold-side mark group 108 and the substrate-side mark group 111 is adjusted via the adjustment unit such that a peak appears in the waveform obtained from the image of each mark. For example, for a region which includes a mark image with highlight detail loss, the reflectance or transmittance with respect to this region is adjusted to increase the amount of light for illuminating the mold-side mark group 108 and the substrate-side mark group 111. For a region which includes a mark image with shadow detail loss, the reflectance or transmittance with respect to this region is adjusted to decrease the amount of light for illuminating the mold-side mark group 108 and the substrate-side mark group 111. With this, it is impossible to obtain each image included in the overlay image 406 with the optimal light amount, and highly accurately obtain (measure) the position of the mark corresponding to each image.

Adjustment of the reflectance of the region which includes the image of each mark of the mold-side mark group 108 and the substrate-side mark group 111 is implemented by the reflection control unit 5031 (control unit 112) selecting the reflective element 5011 to be set in the first state (or the second state) from the plurality of reflective elements 5011. Here, selecting the reflective element 5011 to be set in the first state corresponds to selecting the reflective element 5011 for reflecting light in the direction toward the mold 103 and the substrate 105.

Adjustment of the transmittance of the region which includes the image of each mark of the mold-side mark group 108 and the substrate-side mark group 111 is implemented by the transmission control unit 5071 (control unit 112) selecting the transmissive element 5051 to be set in the third state (or the fourth state) from the plurality of transmissive elements 5051. Here, selecting the transmissive element 5051 to be set in the third state corresponds to selecting the transmissive element 5051 for transmitting light in the direction toward the mold 103 and the substrate 105.

Note that the amount of light for illuminating the mark outside region which does not include each mark of the mold-side mark group 108 and the substrate-side mark group 111 is preferably adjusted, via the adjustment unit, separately from the amount of light for illuminating the mold-side mark group 108 and the substrate-side mark group 111. For example, the amount of light for illuminating the mark outside region is preferably made smaller than the amount of light for illuminating the mold-side mark group 108 and the substrate-side mark group 111, more specifically, set to zero. With this, the influence of stray light or noise from the mark outside region (the pattern other than the mark existing therein) can be reduced, thereby suppressing degradation of the mark measurement accuracy. However, the amount of light for illuminating the mark outside region is not necessarily set to zero, and it is sufficient to decrease the amount to a level that does not affect the mark measurement accuracy.

FIG. 10 is a view illustrating an example of the reflectance or transmittance individually set for each region which includes the image of each mark of the mold-side mark group 108 and the substrate-side mark group 111 in the reflection type adjustment mechanism 206 or the transmission type adjustment mechanism 208. Referring to FIG. 10, for a region 702 which includes the high accuracy Y mark overlay image 405, the maximum reflectance or transmittance is set to prevent saturation of the high accuracy Y mark overlay image 405. For a region 703 which includes the high accuracy X mark overlay image 404, the first reflectance or first transmittance lower than the maximum reflectance or transmittance is set to prevent saturation of the high accuracy X mark overlay image 404. For a region 704 which includes the substrate-side wide range mark image 403, the second reflectance or the second transmittance lower than the first reflectance or the first transmittance is set to prevent saturation of the substrate-side wide range mark image 403. For a region 705 which includes the mold-side wide range mark image 402, the third reflectance or the third transmittance lower than the second reflectance or the second transmittance is set to prevent saturation of the mold-side wide range mark image 402. For a mark outside region 706 which does not include the image of each mark of the mold-side mark group 108 and the substrate-side mark group 111, the minimum reflectance or transmittance is set to reduce influence of stray light, noise, and the like.

FIG. 11 is a view illustrating an example of the result of selecting the reflective elements 5011 or the transmissive elements 5051 for reflecting or transmitting light in the direction toward the mold 103 and the substrate 105 with respect to the reflectance or transmittance of each region illustrated in FIG. 10. In FIG. 11, the reflective element 5011 or the transmissive element 5051 that reflects or transmits light in the direction toward the mold 103 and the substrate 105 is illustrated in white. In this manner, by spatially controlling the reflective elements 5011 or the transmissive elements 5051 for each region which includes the image of each mark of the mold-side mark group 108 and the substrate-side mark group 111, the reflectance or transmittance of each region illustrated in FIG. 10 can be implemented. In other words, in this embodiment, for each region which includes the image of each mark, it is possible to adjust the amount of light for illuminating each mark by selecting the reflective element 5011 or the transmissive element 5051 that reflects or transmits light in the direction toward the mold 103 and the substrate 105.

Note that in this embodiment, the reflective element 5011 or the transmissive element 5051 is set in the state (the first state or the third state) for illuminating the mark, or the state (the second state or the fourth state) for not illuminating the mark. However, in the state in which the reflective element 5011 or the transmissive element 5051 illuminates the mark, the state of the reflective element 5011 or the transmissive element 5051 may be controlled stepwise to give a gradation to the amount of light for illuminating the mark.

It is also possible to adjust the amount of light for illuminating the mold-side mark group 108 and the substrate-side mark group 111 by temporally controlling the reflective element 5011 or the transmissive element 5051 (state thereof) for each region which includes the image of each mark of the mold-side mark group 108 and the substrate-side mark group 111.

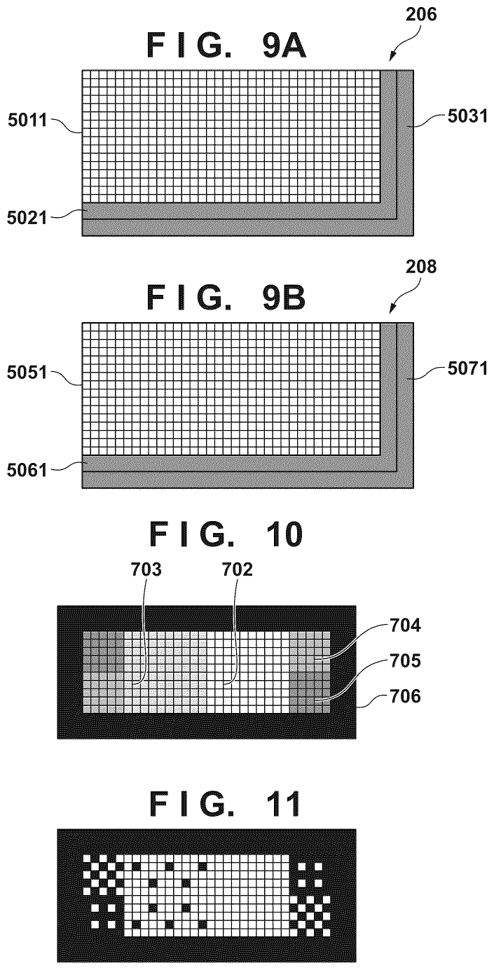

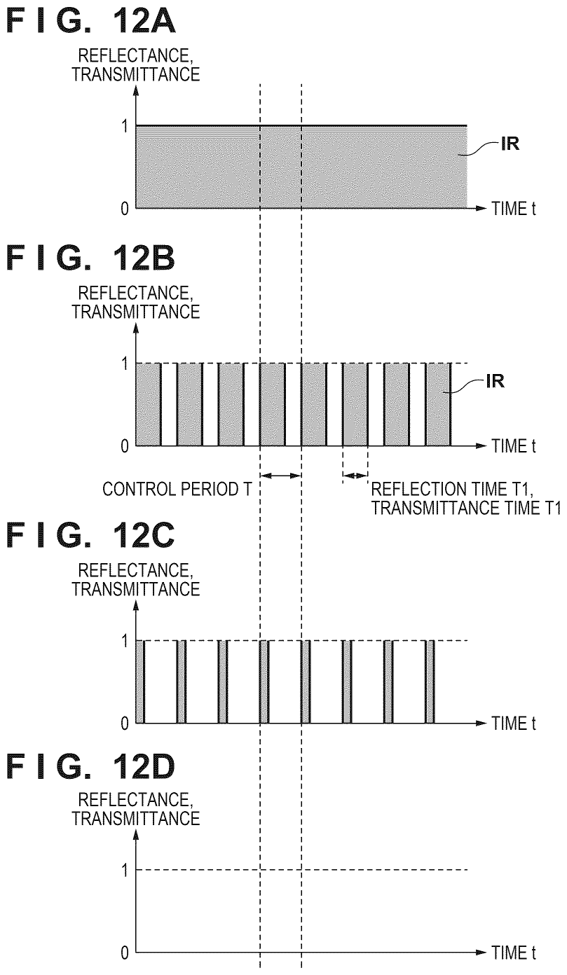

With reference to FIGS. 12A to 12D, temporal control of the state of the reflective element 5011 or the transmissive element 5051 for each region which includes the image of each mark of the mold-side mark group 108 and the substrate-side mark group 111 will be described. In FIGS. 12A to 12D, the ordinate represents the reflectance or transmittance of the region which includes the image of each mark, and the abscissa represents time (t). A region IR indicates the period during which the reflective element 5011 or the transmissive element 5051 is controlled to the first state or the third state for reflecting or transmitting light in the direction toward the mold 103 and the substrate 105.

FIG. 12A illustrates an example of control of the state of the reflective element 5011 or the transmissive element 5051 in a case of setting the reflectance or transmittance of the region which includes the image of each mark to the maximum reflectance or the maximum transmittance. FIG. 12D illustrates an example of control of the state of the reflective element 5011 or the transmissive element 5051 in a case of setting the reflectance or transmittance of the region which includes the image of each mark to the minimum reflectance or the minimum transmittance. Each of FIGS. 12B and 12C illustrates an example of control of the state of the reflective element 5011 or the transmissive element 5051 in a case of setting the reflectance or transmittance of the region which includes the image of each mark to a reflectance or transmittance between the maximum reflectance or the maximum transmittance and the minimum reflectance or the minimum transmittance, respectively.

Referring to FIGS. 12B and 12C, a reflection time or transmittance time T1 for obtaining the necessary reflectance between the maximum reflectance and the minimum reflectance or the necessary transmittance between the maximum transmittance and the minimum transmittance can be obtained by multiplying the necessary reflectance or transmittance by a control period T. For example, in a case where the necessary reflectance or transmittance is 30%, and the control period T is 10 ms, the reflection time or transmittance time T1 is obtained by 10 ms×0.3=0.3 ms. Hence, during the control period T, by controlling the reflective element 5011 or the transmissive element 5051 to the first state or the third state for 3 ms, and controlling it to the second state or the fourth state for 7 ms, the reflectance or transmittance can be set to 30%. Note that the reflection time or transmittance time T1 is adjusted (changed) in accordance with the necessary reflectance or transmittance in the region which includes the image of each mark.

The method of obtaining the necessary reflectance or transmittance in the region which includes the image of each mark of the mold-side mark group 108 and the substrate-side mark group 111 is not limited to spatial or temporal control (thinning) of the reflective elements 5011 or the transmissive elements 5051. For example, it is also possible to obtain the necessary reflectance or transmittance in the region which includes the image of each mark by uniformly controlling the reflective elements 5011 or the transmissive elements 5051 (setting them in the same state). More specifically, by setting the reflectance or transmittance of the reflective element 5011 or the transmissive element 5051 directly to the necessary reflectance or transmittance, it is possible to obtain the necessary reflectance or transmittance in the region which includes the image of each mark even by uniformly controlling the reflective elements 5011 or the transmissive elements 5051. As the method of setting the reflective elements 5011 or the transmissive elements 5051 to have the necessary reflectance or transmittance, for example, it is conceivable to make the reflective element 5011 or the transmissive element 5051 controllable to a plurality of states obtained by dividing the first state or the third state, thereby giving a gradation to the reflectance or transmittance.

More specifically, first, the mold-side mark group 108 and the substrate-side mark group 111 existing in one field of view of the image capturing unit 203 (image capturing device) are simultaneously captured by the image capturing unit 203 to obtain the overlay image 401. With this, the mold-side wide range mark image 402, the substrate-side wide range mark image 403, the high accuracy X mark overlay image 404 (interference fringe), and the high accuracy Y mark overlay image 405 (interference fringe) are obtained simultaneously.

Then, the positions of the mold-side wide range mark image 402 and the substrate-side wide range mark image 403 with respect to the image capturing region of the image capturing unit 203 (image capturing device) are specified, and the positional relationship between the mold-side mark group 108 and the substrate-side mark group 111 is obtained. At the same time, the highly accurate positional relationship between the mold-side mark group 108 and the substrate-side mark group 111 is obtained from the high accuracy X mark overlay image 404 and the high accuracy Y mark overlay image 405.

Here, in this embodiment, since the high accuracy X mark overlay image 404 and the high accuracy Y mark overlay image 405 are interference fringes, in principle, a positional shift larger than the period of the interference fringe cannot be measured. In other words, if the positional relationship between the mold-side mark group 108 and the substrate-side mark group 111 obtained from the mold-side wide range mark image 402 and the substrate-side wide range mark image 403 is not larger than the period of the interference fringe, the highly accurate positional relationship between the mold-side mark group 108 and the substrate-side mark group 111 can be obtained. Accordingly, the resolution of each of the mold-side wide range mark 301 and the substrate-side wide range mark 304 needs to be equal to or lower than the period of the interference fringe generated by the overlay (composition) of the mold-side high accuracy mark and the substrate-side high accuracy mark. Note that the mold-side high accuracy mark includes the mold-side high accuracy X mark 302 and the mold-side high accuracy Y mark 303, and the substrate-side high accuracy mark includes the substrate-side high accuracy X mark 305 and the substrate-side high accuracy Y mark 306. The positional relationship obtained from these high accuracy marks is expressed by the measurement value of the high accuracy mark to which the product of the integer value of the quotient between the wide range mark and the period of the interference fringe and the period of the interference fringe is added.

In this embodiment, from the positional relationship between the substrate-side mark group 111 provided in the shot region on the substrate and the corresponding mold-side mark group 108, and the design position of the substrate-side mark group 111 in the shot region, the positional relationship between the shot region and the mold 103 (the pattern thereof) is obtained. The positional relationship between the shot region on the substrate and the mold 103 (the positional relationship between the mold 103 and the substrate 105) includes, for example, X translation, Y translation, rotation, X magnification, Y magnification, a diamond shape, and the like. As for the positional relationship between the shot region on the substrate and the mold 103, X translation, Y translation, and rotation are reflected on the driving instruction value of the substrate stage 109, and the substrate stage 109 is driven so as to reduce the alignment error. X magnification, Y magnification, and the diamond shape are reflected on the driving instruction value of a magnification/shape correction mechanism, and the magnification/shape correction mechanism is driven so as to reduce the alignment error. The magnification/shape correction mechanism is implemented as, for example, a mechanism that deforms the mold 103 (pattern thereof) by applying a force to the side surface of the mold 103, or a mechanism that deforms the substrate 105 (shot region thereof) by applying heat to the substrate 105. Note that the positional relationship between the shot region on the substrate and the mold 103, and the method of correcting the positional relationship are not limited. In this manner, the mold 103 and the substrate 105 are aligned by repeating the alignment operation while obtaining the positional relationship between the mold 103 and the substrate 105 by simultaneously capturing the mold-side mark group 108 and the substrate-side mark group 111 to obtain the overlay image 401.

Setting of the region which includes the image of each mark of the mold-side mark group 108 and the substrate-side mark group 111 in the overlay image 406 will be described. The region which includes the image of each mark of the mold-side mark group 108 and the substrate-side mark group 111 is basically set based on the design information of each mark, as described above.

However, there can be a case where the position of the substrate-side mark group 111 is shifted with respect to the image capturing region (field of view) of the image capturing unit 203, as illustrated in FIG. 7A. In this case, as illustrated in FIG. 7B, the region which includes the image of each mark may be set based on the position of the image of each mark of the mold-side mark group 108 and the substrate-side mark group 111 in the overlay image 406 (mark image) obtained by the image capturing unit 203. In other words, the regions for detecting the marks may be set in the image capturing unit 203 (image capturing device) so as to include the image of each mark of the mold-side mark group 108 and the substrate-side mark group 111 in the overlay image 406.

During alignment between the mold 103 and the substrate 105, by repeating the alignment operation, the positional relationship between the mold-side mark group 108 and the substrate-side mark group 111 dynamically fluctuates. Therefore, during a period of alignment between the mold 103 and the substrate 105, the region which includes the image of each mark is preferably set dynamically based on the position of the image of each mark of the mold-side mark group 108 and the substrate-side mark group 111 in the overlay image 406 obtained by the image capturing unit 203.

In this manner, setting of each of the regions 601 to 605 in the image capturing unit 203 may be changed in accordance with the position of the substrate-side mark group 111 in the image capturing region (field of view) of the image capturing unit 203. In this case, in accordance with the change of setting of each of the regions 601 to 605 in the image capturing unit 203, an arbitrary region for adjusting the amount of light for illuminating each mark is set in the reflection region of the reflection type adjustment mechanism 206 or in the transmission region of the transmission type adjustment mechanism 208.

There can be a case where, when starting alignment between the mold 103 and the substrate 105, the positional relationship between the mold-side mark group 108 and the substrate-side mark group 111 is significantly shifted. In this case, it is assumed that the image of each mark of the mold-side mark group 108 and the substrate-side mark group 111 is not included in the overlay image 406 obtained by the image capturing unit 203. Accordingly, each mark cannot be detected in the region set based on the design information of each mark of the mold-side mark group 108 and the substrate-side mark group 111. In this case, the setting of the region corresponding to each mark is canceled, and the overlay image 406 is obtained by adjusting the amounts of light for illuminating the respective marks to the same amount in the entire area of the image capturing region of the image capturing unit 203 via the reflection type adjustment mechanism 206 or the transmission region of the transmission type adjustment mechanism 208. Then, a search of the image of each mark of the mold-side mark group 108 and the substrate-side mark group 111 is performed in the overlay image 406, and regions for detecting the respective marks are newly set in the image capturing unit 203 so as to include the images of the respective mark detected by the search. In addition, in accordance with each of the newly set regions 601 to 605, an arbitrary region for adjusting the amount of light for illuminating each mark is set in the reflection region of the reflection type adjustment mechanism 206 or the transmission region of the transmission type adjustment mechanism 208.

Note that, in this embodiment, a case where the positional relationship between the mold-side mark group 108 and the substrate-side mark group 111 is significantly shifted is taken as an example, and adjusting the amounts of light for illuminating the mold-side mark group 108 and the substrate-side mark group 111 to the same amount has been described. However, adjusting the amounts of light for illuminating the mold-side mark group 108 and the substrate-side mark group 111 to the same amount is also useful in a case where the amount of light for illuminating each mark has not been adjusted appropriately. For example, if the amount of light for illuminating each mark is not appropriate, by setting the uniform light amount in the entire area of the image capturing region, it is possible to search for the image of each mark of the mold-side mark group 108 and the substrate-side mark group 111.

In this manner, in this embodiment, the imprint apparatus 100 can obtain the image of each mark of the mold-side mark group 108 and the substrate-side mark group 111 with the optimal light amount, thereby highly accurately obtaining (measuring) the position of the mark corresponding to each image. Hence, according to this embodiment, it is possible to provide a technique advantageous in measuring the relative position between the mold-side mark group 108 and the substrate-side mark group 111, and highly accurately align the mold 103 and the substrate 105.

The pattern of a cured product formed using the imprint apparatus 100 in the embodiment is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

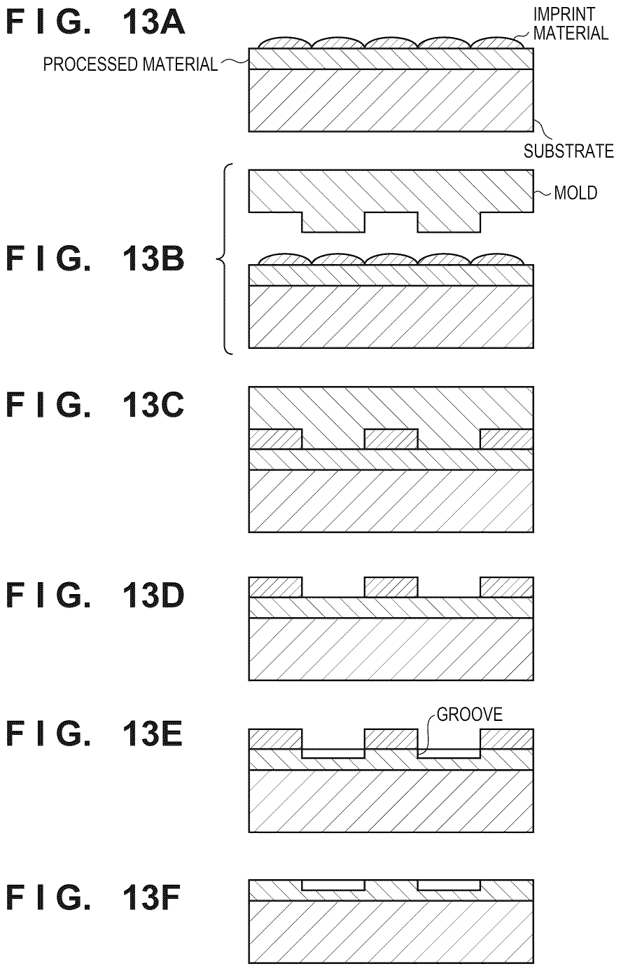

Next, description regarding a detailed method of manufacturing an article is given. As illustrated in FIG. 13A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 13B, a side of the mold for imprint with a projection and groove pattern is formed on and caused to face the imprint material on the substrate. As illustrated in FIG. 13C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 13D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold is transferred to the imprint material.

As shown in FIG. 13E, when etching is performed using the pattern of the cured product as an etching resistant mask, a portion of the surface of the processed material where the cured product does not exist or remains thin is removed to form a groove. As shown in FIG. 13F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

In this embodiment, the imprint apparatus has been described as an example of the lithography apparatus that forms a pattern on a substrate using an original. However, the lithography apparatus is not limited to the imprint apparatus, and may be an exposure apparatus that exposes a substrate by projecting the pattern of an original (a mask or a reticle) onto a substrate, or the like.

While the present disclosure has been described with reference to exemplary embodiments, it is to be understood that the preset disclosure is not limited to the disclosed exemplary embodiments. The scope of the following claims is to be accorded the broadest interpretation so as to encompass all such modifications and equivalent structures and functions.

This application claims the benefit of Japanese Patent application No. 2024-158481 filed on Sep. 12, 2024 and Japanese Patent application No. 2024-158483 filed on Sep. 12, 2024 which are hereby incorporated by reference herein in its entirety.

According to the present disclosure, for example, a technique advantageous in alignment between an original and a substrate can be provided.

1. A lithography apparatus that forms a pattern in a curable composition on a substrate using an original, comprising:
a measurement unit configured to obtain a mark image by simultaneously capturing a first mark group provided in the original and a second mark group provided in the substrate, which exist in one field of view, and measure a relative position between the first mark group and the second mark group; and
a control unit configured to align the original and the substrate based on the relative position while measuring the relative position by the measurement unit,
wherein the control unit adjusts an image capturing condition for each region which includes an image of each mark of the first mark group and the second mark group.

2. The apparatus according to claim 1, wherein
the first mark group includes a first coarse detection mark and a first fine detection mark, and the second mark group includes a second coarse detection mark and a second fine detection mark to be combined with the first fine detection mark, and
the control unit controls the measurement unit so as to simultaneously capture the first coarse detection mark, the second coarse detection mark, and a combination of the first fine detection mark and the second fine detection mark.

3. The apparatus according to claim 2, wherein
a resolution of each of the first coarse detection mark and the second coarse detection mark is not more than a period of an interference fringe generated by a combination of the first fine detection mark and the second fine detection mark.

4. The apparatus according to claim 1, wherein
the measurement unit includes a plurality of pixels configured to detect light from each mark of the first mark group and the second mark group, and
the image capturing condition includes a sensitivity of detecting the light by each of the plurality of pixels.

5. The apparatus according to claim 1, wherein
the measurement unit includes a plurality of pixels configured to detect light from each mark of the first mark group and the second mark group, and
the image capturing condition includes an accumulation time of accumulating the light by each of the plurality of pixels.

6. The apparatus according to claim 1, wherein
the measurement unit includes a plurality of pixels configured to detect light from each mark of the first mark group and the second mark group, and
the image capturing condition includes a gain at the time of converting the light detected by each of the plurality of pixels into an electric signal.

7. The apparatus according to claim 1, wherein
the control unit sets the region based on design information of each mark of the first mark group and the second mark group.

8. The apparatus according to claim 1, wherein
the control unit sets the region based on a position of an image of each mark of the first mark group and the second mark group in the mark image obtained by the measurement unit.

9. The apparatus according to claim 1, wherein
the control unit dynamically sets the region based on a position of an image of each mark of the first mark group and the second mark group in the mark image obtained by the measurement unit during a period of alignment between the original and the substrate.

10. The apparatus according to claim 1, wherein
in a case where an image of each mark of the first mark group and the second mark group is not included in the mark image, the control unit adjusts the image capturing conditions to the same condition in the entire area of an image capturing region for capturing the first mark group and the second mark group.

11. The apparatus according to claim 1, wherein
at least one of the first mark group and the second mark group includes a plurality of marks having different optical characteristics.

12. The apparatus according to claim 1, wherein
the control unit adjusts the image capturing condition for each region such that a peak appears in a waveform obtained from an image of each mark of the first mark group and the second mark group.

13. The apparatus according to claim 1, wherein
the original and the curable composition are brought into contact with each other to form a pattern of the curable composition with a pattern of the original transferred thereto.

14. A lithography method of forming a pattern in a curable composition on a substrate using an original, comprising:
aligning the original and the substrate based on a relative position while obtaining a mark image by simultaneously capturing a first mark group provided in the original and a second mark group provided in the substrate, which exist in one field of view, and measuring the relative position between the first mark group and the second mark group; and
adjusting an image capturing condition for each region which includes an image of each mark of the first mark group and the second mark group.

15. A measurement apparatus that measures a relative position between a first mark group provided in an original and a second mark group provided in a substrate, comprising:
an image capturing device configured to obtain a mark image by simultaneously capturing the first mark group and the second mark group existing in one field of view;
an adjustment unit configured to adjust an amount of light for illuminating the first mark group and the second mark group; and
a control unit configured to adjust the amount of light via the adjustment unit for each region which includes an image of each mark of the first mark group and the second mark group.

16. The apparatus according to claim 15, wherein
the adjustment unit includes a plurality of reflective elements arrayed in a grid, and
the control unit adjusts the amount of light by selecting, for each region, a reflective element that reflects the light in a direction toward the first mark group and the second mark group from the plurality of reflective elements.

17. The apparatus according to claim 16, wherein
the control unit adjusts the amount of light by spatially or temporally selecting, for each region, a reflective element that reflects the light in a direction toward the first mark group and the second mark group.

18. The apparatus according to claim 15, wherein
the adjustment unit includes a plurality of transmissive elements arrayed in a grid, and
the control unit adjusts the amount of light by selecting, for each region, a transmissive element that transmits the light in a direction toward the first mark group and the second mark group from the plurality of transmissive elements.

19. The apparatus according to claim 18, wherein
the control unit adjusts the amount of light by spatially or temporally selecting, for each region, a transmissive element that transmits the light in a direction toward the first mark group and the second mark group.

20. The apparatus according to claim 15, wherein
the adjustment unit is arranged at a position defocused from an intermediate imaging position of light for illuminating the first mark group and the second mark group.

21. The apparatus according to claim 20, wherein
a position defocused from the intermediate imaging position is a position where illuminance unevenness of light entering the first mark group and the second mark group via the adjustment unit becomes not more than 10%.

22. The apparatus according to claim 15, wherein
the control unit adjusts, via the adjustment unit, an amount of light for illuminating a mark outside region, which does not include each mark of the first mark group and the second mark group, separately from an amount of light for illuminating the first mark group and the second mark group.

23. The apparatus according to claim 22, wherein
the control unit makes, via the adjustment unit, an amount of light for illuminating the mark outside region smaller than an amount of light for illuminating the first mark group and the second mark group.

24. The apparatus according to claim 23, wherein
the control unit sets, via the adjustment unit, an amount of light for illuminating the mark outside region to zero.

25. The apparatus according to claim 15, wherein
the control unit sets the region based on design information of each mark of the first mark group and the second mark group.

26. The apparatus according to claim 15, wherein
the control unit sets the region based on a position of an image of each mark of the first mark group and the second mark group in the mark image obtained by the image capturing device.

27. The apparatus according to claim 15, wherein
the control unit dramatically sets the region based on a position of an image of each mark of the first mark group and the second mark group in the mark image obtained by the image capturing device during a period of measuring the relative position.

28. The apparatus according to claim 15, wherein
in a case where an image of each mark of the first mark group and the second mark group is not included in the mark image, the control unit adjusts, via the adjustment unit, the amounts of light to the same amount in the entire area of an image capturing region for capturing the first mark group and the second mark group.

29. The apparatus according to claim 15, wherein
at least one of the first mark group and the second mark group includes a plurality of marks having different optical characteristics.

30. The apparatus according to claim 15, wherein
the first mark group includes a first coarse detection mark and a first fine detection mark, and the second mark group includes a second coarse detection mark and a second fine detection mark to be combined with the first fine detection mark.

31. A lithography apparatus that forms a pattern in a curable composition on a substrate using an original, comprising:
a measurement unit configured to measure a relative position between a first mark group provided in the original and a second mark group provided in the substrate; and
an alignment unit configured to align the original and the substrate based on the relative position while measuring the relative position by the measurement unit,
wherein the measurement unit includes an image capturing device configured to obtain a mark image by simultaneously capturing the first mark group and the second mark group existing in one field of view,
an adjustment unit configured to adjust an amount of light for illuminating the first mark group and the second mark group, and
a control unit configured to adjust the amount of light via the adjustment unit for each region which includes an image of each mark of the first mark group and the second mark group.

32. The apparatus according to claim 31, wherein
the original and the curable composition are brought into contact with each other to form a pattern of the curable composition with a pattern of the original transferred thereto.

33. An article manufacturing method comprising:
forming a pattern on a substrate using a lithography apparatus defined in claim 1;
processing the substrate on which the pattern is formed in the forming; and
manufacturing an article from the processed substrate.
